(19) United States
(12) Patent Application Publication
(10) Pub. No.: US 2017/0251571 A1
(43) Pub. Date: Aug. 31, 2017

(54) CURABLE THERMAL INTERFACE MATERIAL AND COOLING DEVICE, AND COOLING DEVICE MANUFACTURING METHOD THEREOF

(71) Applicant: SHIU LI TECHNOLOGY CO., LTD, Taoyuan City (TW)

(72) Inventor: CHUNG-CHENG CHIEN, Taoyuan City (TW)

(73) Assignee: SHIU LI TECHNOLOGY CO., LTD

(21) Appl. No.: 15/135,061

(22) Filed: Apr. 21, 2016

(30) Foreign Application Priority Data
Feb. 25, 2016 (TW) 105202659

(51) Int. Cl. H05K 7/20; F28F 21/02; B41F 23/04; F28F 21/04; F28F 3/08; F28F 21/06; F28F 21/08

(52) U.S. Cl. CPC H05K 7/20427; F28F 21/067; F28F 21/02; F28F 21/084; F28F 21/081; F28F 21/04; F28F 3/08; B41F 23/0476; F28F 2013/006

(57) ABSTRACT

A curable thermal interface material and a cooling device, and a cooling device manufacturing method thereof are provided. The curable thermal interface material includes thermal conductive material and polymeric material, which is formed from the mixture of thermal conductive material and polymeric material. The curable thermal interface material is disposed on the heat sink, so as to properly conduct heat from the heat source to the heat sink to achieve heat dissipation.

### CROSS-REFFERENCE TO RELATED APPLICATION

This application claims priority from Taiwan Patent Application No. 105202659, filed on Feb. 25, 2016, in the Taiwan Intellectual Property Office, the content of which is hereby incorporated by reference in its entirety for all purposes.

### BACKGROUND OF THE INVENTION

1. Field of the Invention

The present invention relates to the technology of heat conduction and heat dissipation, and more specifically, relates to a curable thermal interface material and a cooling device, and a cooling device manufacturing method thereof.

2. Description of the Related Art

Electronics nowadays are getting smaller as technology advances, consequently, the product stability becomes important, thus making the importance of thermal management more pronounced; regardless of the types of the electronic devices, be it notebooks, desktops, smartphones or any other similar devices, if such device is not cooled down by transferring heat to the heat sink in an appropriate amount of time, then the electronic components inside may be damaged, hence reducing the lifespan of electronics, causing unstable operation, etc. However, there are three ways to transfer heat from the heat source to the heat sink, namely, radiation, convection, and conduction, with conduction being the most effective one. In the known art, in order to transfer heat from the heat source to the heat sink in a proper manner, the thermal grease or thermal pad are conventionally disposed between the heat source and the heat sink.

There are certain shortcomings in the thermal grease and thermal pad, nevertheless. Wherein, thermal grease requires high manpower during preparation, and moreover, being a non-curable thermal interface material which tends to flow in the direction of gravity due to gravitation, sagging may take place. Besides, thermal grease may spill out during assembly and dry out after a long period of time.

Thermal pad is preferably thinner and softer, for the sake of better heat conductivity. However, the thinner and softer thermal pad makes the installation thereof to the heat sink difficult. Furthermore, adhesives such as double-sided tapes are typically applied in order to secure the thermal pad on the heat sink, despite the fact that adhesives will block or hinder thermal conduction. Furthermore, the alignment and adhesion of thermal pad require a considerable amount of labor.

Taking into account of the problems presented, the inventor of present invention who has been making extensive research in the relevant art, designs a curable thermal interface material and a cooling device, and a cooling device manufacturing method thereof, so as to improve current drawbacks in the art, thereby promoting industrial implementation.

### SUMMARY OF THE INVENTION

In light of the aforementioned problems, the objective of the present invention is to provide a curable thermal interface material and a cooling device, and a cooling device manufacturing method thereof, in order to solve the problem in the known art.

In accordance with the objective of the present invention, a curable thermal interface material is provided, which is configured to be disposed between the heat sink and at least one heat source. Curable heat interface material includes a thermal conductive material and a polymeric material. In which, the thermal conductive material makes up 40-95% of the total weight of the curable thermal interface material.

Preferably, the invention may further include an artificial graphite sheet, which is stacked in the curable thermal interface material.

Preferably, the thermal conductive material may include aluminum oxide, aluminum nitride, zinc oxide, silicon carbide, boron nitride, graphene, artificial graphite sheet, magnesium oxide or aluminum composite whereas the polymeric material may include silicone, epoxy, acrylic acid, polyurethane or rubber.

Preferably, the thickness of the curable thermal interface material after being disposed on the heat sink may range from 0.01 to 5 mm.

Preferably, the hardness of the curable thermal interface material after curing may range from 10 Shore 000 to 90 Shore 00 in Shore Hardness Scale.

Preferably, the curable thermal interface material is a thermosetting type, or a phase change type transforming into liquid state at temperature ranging from 42 to 75° C.

In accordance with the objective of the present invention, a cooling device is further provided in order to cool down at least one heat source. The cooling device includes a heat sink and a curable thermal interface material. Wherein, the cooling device has a disposing surface facing at least one heat source while the curable thermal interface material is attached to the disposing surface by bonding. Wherein, the curable thermal interface material includes a thermal conductive material and a polymeric material. Wherein, the thermal conductive material makes up 40 to 95% of the total weight of the curable thermal interface material.

Preferably, the curable thermal interface material is stacked with the artificial graphite sheet.

Preferably, a thermal radiation coating is disposed on a portion or the entire surface of the heat sink.

In accordance with the objective of the present invention, a cooling device manufacturing method is provided, which includes the following steps: providing a heat sink; mixing the thermal conductive material with the polymeric material in order to form the curable thermal interface material in liquid state, wherein the thermal conductive material makes up 40 to 95% of the total weight of the curable thermal interface material; and applying the curable thermal interface material to a disposing surface of the heat sink via screen printing process, stamping process, board printing process or pressing process, wherein the curable thermal interface material bonds to the disposing surface of the heat sink during curing.

Preferably, the method further includes a step of stacking the curable thermal interface material with the artificial graphite sheet.

Preferably, the method further includes a step of spraying the thermal radiation paint on a portion or the entire surface of the heat sink to form a thermal radiation coating.

The curable thermal interface material and the cooling device, and the cooling device manufacturing method thereof of the present invention may come with one or more advantages listed below:

(1) With the present invention, the curable thermal interface material can be disposed firmly on the heat sink by bonding to the heat sink during curing, thereby facilitating the subsequent attachment of the heat sink to the heat source, as well as eliminating the need for adhesives such that blocking or hindrance of thermal conduction can be avoided.

(2) With the present invention, the curable thermal interface material which is in liquid state during initial application can fill the gaps on the surface of the heat sink properly, thus achieving excellent thermal conductivity; in addition the present invention hardens into solid after heating or subjecting to ambient temperature, which solves the problem of sagging, spilling out or drying out, avoiding the deterioration in performance of the electronic devices due to poor cooling efficiency after prolonged usage.

(3) With the present invention, a curable thermal interface material with predetermined thickness can match heat sources with varying heights, further improving the usability.

(4) With the present invention, the curable thermal interface material can be applied on the heat sink via the screen printing process, stamping process, board printing process or pressing process, and the curable thermal interface material can be applied on a plurality of heat sinks at the same time, thereby saving labor and time.

(5) With the present invention, a thinner layer of curable thermal interface material can be applied on the heat sink via a preselected application process, such as the screen printing process, in the meantime, the hardness of the curable thermal interface material can be adjusted by varying the ratio of thermal conductive material to the polymeric material, so that good thermal conductivity is achieved.

(6) With the present invention, the curable thermal interface material can be stacked with the artificial graphite sheet, wherein the artificial graphite sheet can disperse heat homogeneously, such that better thermal conductivity is achieved.

(7) With the present invention, the cooling efficiency of the heat sink can be further improved by the thermal radiation coating on the heat sink.

### BRIEF DESCRIPTION OF THE DRAWINGS

FIG. 1 is a schematic diagram illustrating the cooling device of the present invention.

FIG. 2 is a schematic diagram illustrating another embodiment of the curable thermal interface material of the cooling device of the present invention.

FIG. 3 is a flowchart illustrating the manufacture of the cooling device of the present invention.

FIG. 4 is a schematic diagram illustrating the application of the curable thermal interface material of the present invention.

FIG. 5 is a schematic diagram illustrating the first application of the cooling device in the present invention.

FIG. 6 is a schematic diagram illustrating the second application of the cooling device in the present invention.

FIG. 7 is a schematic diagram illustrating another embodiment of the cooling device of the present invention.

### DESCRIPTION OF THE PREFERRED EMBODIMENTS

Various aspects like the technical features, advantages or content of the present invention will be set forth in detail in the form of preferred embodiments hereinafter, description will be made along with reference to the attached drawings, which are solely illustrative and serve to provide better understanding of the present invention only, the scale and/or proportion of any portion of the drawing do not represent the actual configuration of the invention, hence the scale, proportion or shape in the drawings should not be misconstrued as limiting the scope of the invention.

Hereinafter, the curable thermal interface material and the cooling device, and the cooling device manufacturing method thereof of the present invention will be set forth with respect to the accompanying drawings; similar elements in the embodiments will be assigned with similar numerals for the clarity of the description.

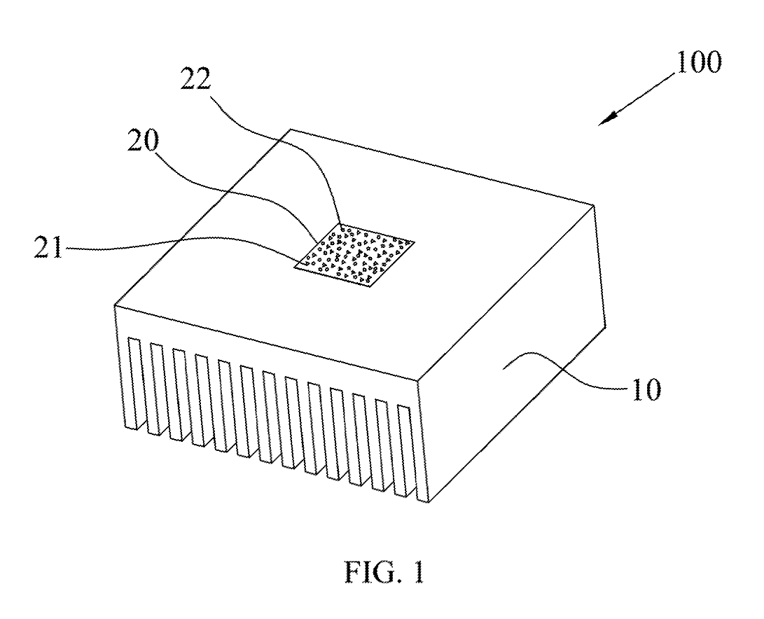

FIG. 1 is a schematic diagram illustrating the cooling device of the present invention. As what can be appreciated in FIG. 1, cooling device 100 of the present invention is mainly applied to cool down at least one heat source, wherein the heat source can be a CPU, a chip, or an electronic component on a motherboard, but not limited thereto, as any component which generates heat during operation can be called a heat source. The cooling device 100 includes the heat sink 10 and the curable thermal interface material 20. Wherein, the heat sink 10 can be formed by aluminum extrusion or die-casting as well as stacking aluminum or copper fins and selectively disposing with the heat pipe, the heat sink 10 can even be the housing of electronic devices. The curable thermal interface material 20 includes a thermal conductive material 21 and a polymeric material 22. In other words, the curable thermal interface material 20 is made of at least a mixture of the thermal conductive material 21 and the polymeric material 22. In which, the thermal conductive material 21 includes aluminum oxide, aluminum nitride, zinc oxide, silicon carbide, boron nitride, graphene, artificial graphite sheet, magnesium oxide or aluminum composite; while the polymeric material 22 includes silicone, epoxy such as silicon epoxy ester, acrylic acid, polyurethane or rubber, the thermal conductive material 21 and the polymeric material 22 respectively make up 40-95% and 5-60% of the total weight of the curable thermal interface material 20.

That is to say, the cooling device 100 of the present invention can conduct heat from the heat source to the heat sink 10 via the curable thermal interface material 20, and subsequently dissipate heat from the heat sink 10 by thermal convection. Due to the excellent heat conductivity of the curable thermal interface material 20, the cooling device 100 of the present invention possesses outstanding cooling efficiency.

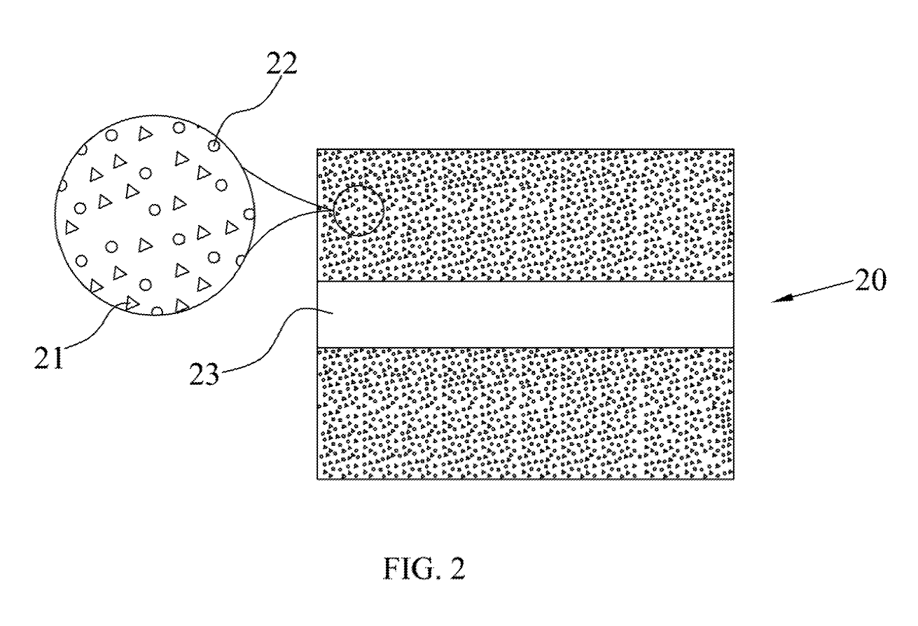

Reference should be made along with FIG. 2, which is a schematic diagram illustrating another embodiment of the curable thermal interface material of the cooling device of the present invention. As shown in the figure, in another preferred embodiment, the curable thermal interface material 20 can be formed by mixing at least the thermal conductive material 21 with the polymeric material 22, and subsequently stacking the mixture with the artificial graphite sheet 23. For example, the present embodiment can be implemented by stacking the mixture of the thermal conductive material 21 and the polymeric material 22 at both sides of the artificial graphite sheet 23. Therefore, the artificial graphite sheet 23 can be used to disperse heat homogeneously, such that better thermal conductivity can be achieved. However, FIG. 2 is merely illustrative of an exemplary embodiment, the curable thermal interface material 20 can be disposed on the heat sink 10 independently which is shown in FIG. 1, therefore the invention should not be limited by the configuration of present embodiment.

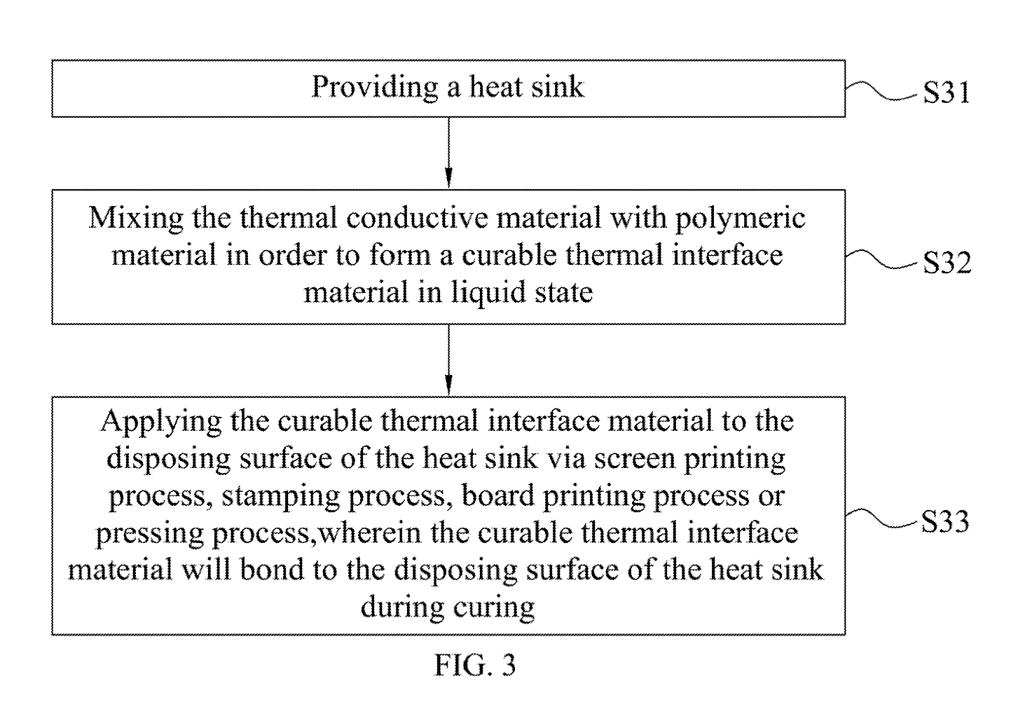

Refer to FIG. 3, which is a flowchart illustrating the manufacture of the cooling device of the present invention. The figure indicates that the cooling device 100 of the present invention can be manufactured with the following steps: (S31) providing a heat sink; (S32) mixing the thermal conductive material with the polymeric material in order to form a curable thermal interface material in liquid state; and (S33) applying the curable thermal interface material to the disposing surface of the heat sink via screen printing process, stamping process, board printing process or pressing process, wherein the curable thermal interface material will bond to the disposing surface of the heat sink during curing.

It is noteworthy that, the curable thermal interface material 20 can be a thermosetting or a phase change type curable thermal interface material 20. Wherein, the term “curable” of the curable thermal interface material 20 refers to the process of hardening that after the mixture of the thermal conductive material 21 and the polymeric material 22, the mixture which is initially in a liquid state will harden into solid after subjected to the ambient temperature or the baking process. For example, the heat sink 10 with the curable thermal interface material 20 applied thereon can be disposed on the plastic tray and subjected to the ambient temperature, the curable thermal interface material 20 will then harden into solid; or as an alternative, the curable thermal interface material 20 can cure after being baked at 90 to 120° C. for 5-30 minutes. It is apparent that the curable thermal interface material 20 will cure in a shorter time by baking comparing to subjecting to ambient temperature; and therefore either baking or subjecting to ambient temperature can be applied according to the actual requirements. Wherein, for the phase change type curable thermal interface material 20, the mixture of thermal conductive material 21 and the polymeric material 22 which is initially in liquid state, hardens into solid after being subjected to ambient temperature, and transforms back into liquid state when the curable thermal interface material 20 is heated to a predetermined temperature, such as 42 to 75° C.

Since the mixture of thermal conductive material 21 and the polymeric material 22 for the curable thermal interface material 20 is in liquid state initially, the curable thermal interface material 20 can properly fill the gaps on the disposing surface of the heat sink 10. Furthermore, the curable thermal interface material 20 can form chemical bond with the disposing surface of the heat sink 10 during curing; hence the curable thermal interface material 20 can be firmly disposed on the heat sink 10. Apart from that, despite the curable thermal interface material 20 being a solid after curing, the curable thermal interface material 20 can still possess flexibility ranging from 10 Shore 000 to 90 Shore 00 in Shore Hardness Scale, which is equivalent to that of the rubber, therefore, curable thermal interface material 20 can be used to fill the gaps and even serves as cushion.

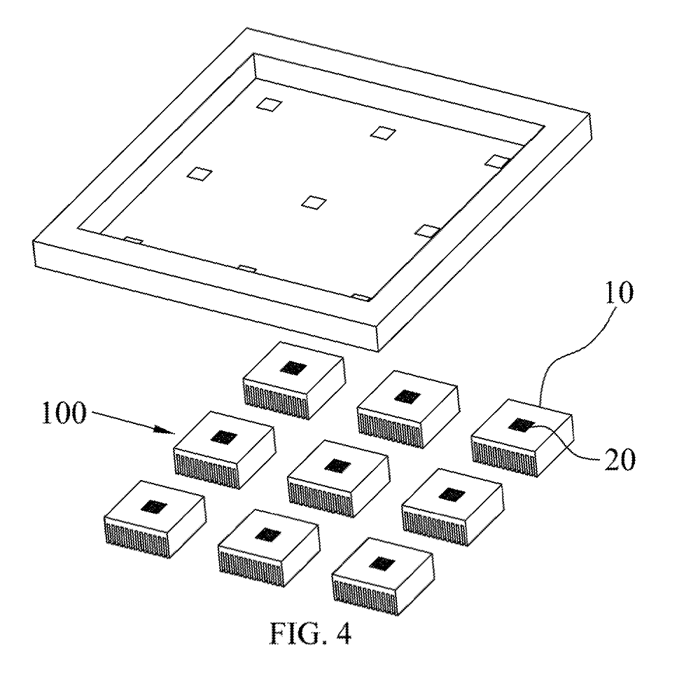

Refer to FIG. 4, which is a schematic diagram illustrating the application of the curable thermal interface material of the present invention. As shown in the figure, the process such as screen printing process, stamping process, board printing process or pressing process can be deployed to apply the curable thermal interface material 20 on a plurality of heat sinks 10 such that considerable amount of labor and time can be saved.

Besides, the process to apply the curable thermal interface material 20 on the heat sink 10 can be chosen based on the actual needs; for example, if the curable thermal interface material 20 to be applied on the heat sink 10 is relatively thin, screen printing or stamping process can be selectively deployed to produce the desired thickness. If the curable thermal interface material 20 to be applied on the heat sink 10 is relatively thick, board printing process or pressing process can be selectively deployed. In other words, the thickness of the curable thermal interface material 20 after being applied on the heat sink 10 can range from 0.01 to 5 mm.

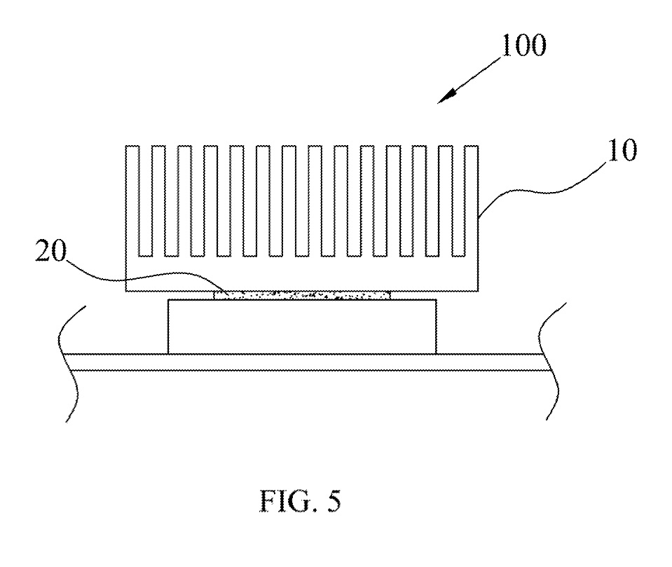

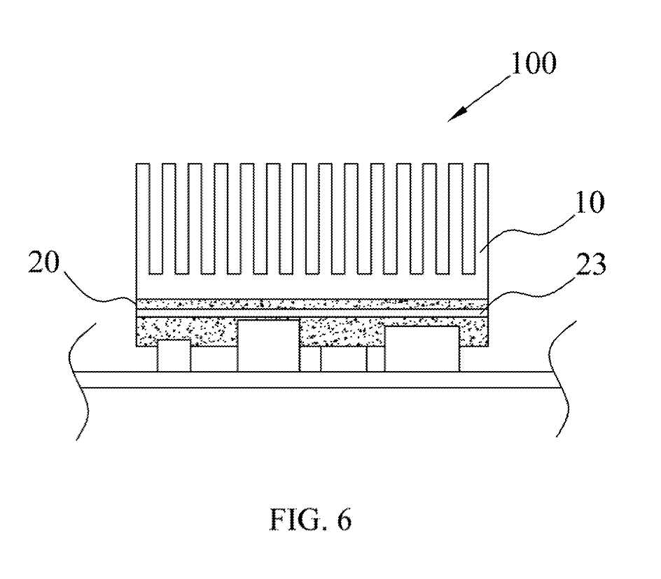

Refer to FIGS. 5 and 6 altogether, which are schematic diagrams respectively illustrating the first application and the second application of the cooling device of the present invention. FIGS. 5 and 6 respectively illustrate that the curable thermal interface material 20 with different thickness can be chosen when different amount of heat sources is applied.

As shown in FIG. 5, when the cooling device 100 of the present invention is applied to only one heat source, such as CPU, the curable thermal interface material 20 applied on the heat sink 10 has to be thinner, such that the curable thermal interface material 20 functions properly as a thermal conduction link between heat sink 10 and the heat source; in addition, the curable thermal interface material 20 is able to serve as a good medium for thermal conduction owing to the optimal thickness thereof.

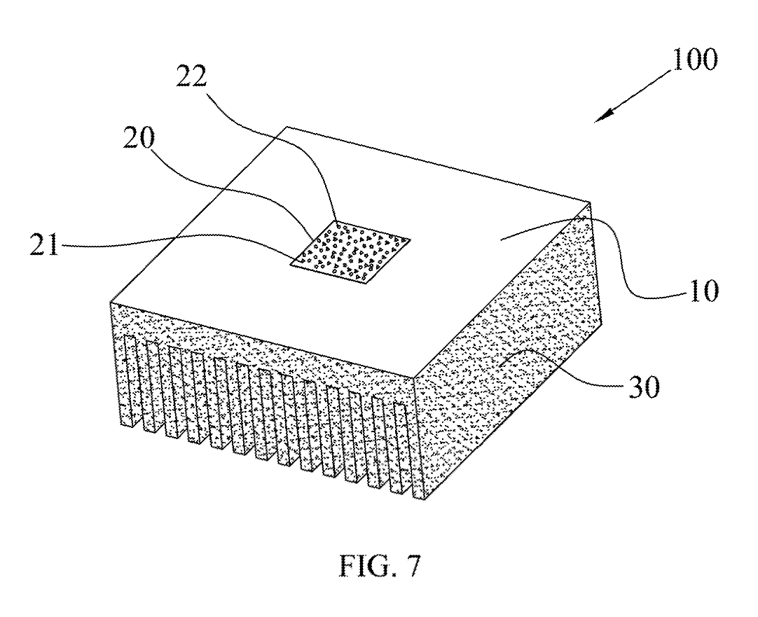

FIG. 7 is a schematic diagram illustrating the other embodiment of the cooling device of the present invention. In this embodiment, elements with similar numerals are configured and function in similar fashion, so unnecessary descriptions are omitted. One can observe from the drawings that the biggest difference between the cooling device 100 of present embodiment and that of the former one is that a portion or all of the surface of the heat sink 10 without the curable thermal interface material 20 is disposed with a thermal radiation coating 30. Wherein, the thermal radiation coating 30 is formed by spraying thermal radiation paint on a portion or all of the surface pf the heat sink 10 without the curable thermal interface material 20.

Thermal radiation paint may include the thermal conductive material 21 and the polymeric material 22. Whereas, conventional spraying equipment with nozzle size ranging from 1.0 to 1.3 mm, nozzle exit pressure ranging from 30 to 40 psi, spray distance ranging from 15 to 30 cm can be adopted for the spraying of the thermal radiation paint; one can touch the thermal radiation paint without leaving any print thereon by subjecting the paint to ambient temperature, the dry up can be hastened by baking in the oven, preferably at 45-90° C. for 10-60 minutes, which will achieve fast dry up and enhance the physical properties of the paint.

With the application of the thermal radiation coating 30 on the heat sink 10 of the cooling device 100 in the present embodiment, the heat sink 10 can dissipate heat by thermal convection and thermal radiation in the meantime.

The foregoing descriptions are only for illustrative instead of restrictive purpose. It is apparent to a person skilled in the art that various modifications and alterations can be made to the embodiments without departing from the spirit and scope of the invention, therefor such modification should be included in the scope of the claims hereinafter.

What is claimed is:

1. A curable thermal interface material configured to be disposed between a heat sink and at least one heat source, comprising a thermal conductive material and a polymeric material; wherein, the thermal conductive material makes up 40 to 95% of a total weight of the curable thermal interface material.

2. The curable thermal interface material of claim 1, further comprising an artificial graphite sheet stacked in the curable thermal interface material.

3. The curable thermal interface material of claim 1, wherein the thermal conductive material comprises aluminum oxide, aluminum nitride, zinc oxide, silicon carbide, boron nitride, graphene, artificial graphite sheet, magnesium oxide or aluminum composite while the polymeric material comprises silicone, epoxy, acrylic acid, polyurethane or rubber.

4. The curable thermal interface material of claim 1, wherein a thickness of the curable thermal interface material after being disposed on the heat sink ranges from 0.01 to 5 mm.

5. The curable thermal interface material of claim 1, wherein a hardness of the curable thermal interface material after curing ranges from 10 Shore 000 to 90 Shore 00 in Shore Hardness Scale.

6. The curable thermal interface material of claim 1, wherein the curable thermal interface material is a thermosetting type, or a phase change type transforming into liquid state at temperature ranging from 42 to 75° C.

7. A cooling device cooling at least one heat source, comprising:
a heat sink having a disposing surface facing at least one heat source; and
a curable thermal interface material attached to the disposing surface of the heat sink by bonding; the curable thermal interface material comprising a thermal conductive material and a polymeric material; wherein, the thermal conductive material makes up 40 to 95% of a total weight of the curable thermal interface material.

8. The cooling device of claim 7, wherein the thermal conductive material comprises aluminum oxide, aluminum nitride, zinc oxide, silicon carbide, boron nitride, graphene, artificial graphite sheet, magnesium oxide or aluminum composite while the polymeric material comprises silicone, epoxy, acrylic acid, polyurethane or rubber.

9. The cooling device of claim 7, wherein a thickness of the curable thermal interface material after being disposed on the heat sink ranges from 0.01 to 5 mm.

10. The cooling device of claim 7, wherein a hardness of the curable thermal interface material after curing ranges from 10 Shore 000 to 90 Shore 00 in Shore Hardness Scale.

11. The cooling device of claim 7, wherein the curable thermal interface material is stacked with an artificial graphite sheet.

12. The cooling device of claim 7, wherein a portion or all of a surface of the heat sink is disposed with a thermal radiation coating.

13. A cooling device manufacturing method, comprising following steps:
providing a heat sink;
mixing a thermal conductive material with a polymeric material in order to form a curable thermal interface material in liquid state, wherein the thermal conductive material makes up 40 to 95% of a total weight of the curable thermal interface material; and
applying the curable thermal interface material to a disposing surface of the heat sink via screen printing process, stamping process, board printing process or pressing process, wherein the curable thermal interface material bonds to the disposing surface of the heat sink during curing.

14. The cooling device manufacturing method of claim 13, further comprising:
stacking the curable thermal interface material with an artificial graphite sheet.

15. The cooling device manufacturing method of claim 13, further comprising:
spraying a thermal radiation paint on a portion or all of a surface of the heat sink to form a thermal radiation coating.

16. The cooling device manufacturing method of claim 13, wherein the thermal conductive material comprises aluminum oxide, aluminum nitride, zinc oxide, silicon carbide, boron nitride, graphene, artificial graphite sheet, magnesium oxide or aluminum composite while the polymeric material comprises silicone, epoxy, acrylic acid, polyurethane or rubber.

17. The cooling device manufacturing method of claim 13, wherein a thickness of the curable thermal interface material after being disposed on the heat sink ranges from 0.01 to 5 mm.

18. The cooling device manufacturing method of claim 13, wherein a hardness of the curable thermal interface material after curing ranges from 10 Shore 000 to 90 Shore 00 in Shore Hardness Scale.
